(19) United States
(12) Patent Application Publication
(10) Pub. No.: US 2025/0312890 A1
(43) Pub. Date: Oct. 9, 2025

(54) INITIALIZATION DEVICE FOR ELASTIC MEMBRANE, POLISHING APPARATUS, INITIALIZATION METHOD FOR ELASTIC MEMBRANE, AND LIFE DETERMINATION METHOD FOR ELASTIC MEMBRANE

(71) Applicant: EBARA CORPORATION, Tokyo (JP)

(72) Inventors: Kenichiro SAITO, Tokyo (JP); Seiji MURATA, Tokyo (JP); Tetsuya TERADA, Tokyo (JP); Kentaro ASANO, Tokyo (JP)

(21) Appl. No.: 18/859,107

(22) PCT Filed: Jan. 20, 2023
(86) PCT No.: PCT/JP2023/001620

§ 371 Date: Oct. 22, 2024

(30) Foreign Application Priority Data
Apr. 27, 2022 (JP) 2022-073348

(51) Int. Cl. B24B 49/16; B24B 37/30

(52) U.S. Cl. CPC B24B 49/16; B24B 37/30

(57) ABSTRACT

The present invention relates to an initialization device for an elastic membrane, a polishing apparatus, an initialization method for an elastic membrane, and a life determination method for an elastic membrane. The initialization device (50) for the elastic membrane (10) includes a pressurizing device (55), an expansion amount detection device (58), and a control device (40) configured to compare an expansion amount detected by the expansion amount detection device (58) with a predetermined target expansion amount, and when the expansion amount reaches the target expansion amount, determine a completion of an initialization of the elastic membrane (10).

### TECHNICAL FIELD

The present invention relates to an initialization device for an elastic membrane, a polishing apparatus, an initialization method for an elastic membrane, and a life determination method for an elastic membrane.

### BACKGROUND ART

In a polishing apparatus for performing a CMP (Chemical Mechanical Polishing), a substrate such as a wafer is held by a substrate holding mechanism (or substrate holding device) called a top ring or polishing head, etc., and the substrate is pressed with a predetermined pressure against a polishing surface of a polishing pad held on a polishing table. At this time, the polishing table and the substrate holding mechanism are moved relative to each other to bring the substrate into sliding contact with the polishing surface of the polishing pad, thereby polishing the surface of the substrate.

If a relative pressing force between the substrate and the polishing surface of the polishing pad during polishing is not uniform over an entire surface of the substrate, insufficient polishing or overpolishing occurs depending on the pressing force applied to each part of the substrate. Therefore, in order to equalize the pressing force applied to the substrate, a pressure chamber formed of a flexible elastic membrane is provided below the substrate holding mechanism, and a fluid such as air is supplied to the pressure chamber to press the substrate by a fluid pressure via the elastic membrane.

### CITATION LIST

### Patent Literature

Patent document 1: Japanese laid-open patent publication No. 2019-077028

### SUMMARY OF INVENTION

### Technical Problem

When a polishing process of the substrate is repeated in the polishing apparatus, the state of the elastic membrane changes. The elastic membrane whose state has changed needs to be replaced with a new elastic membrane. Conventionally, a replacement time of the elastic membrane (i.e., a life of the elastic membrane) has been uniformly determined based on experience such as past process performance (e.g., the number of substrates processed). However, it is desirable to appropriately determine the state of the elastic membrane (more specifically, the replacement time) according to individual differences from a viewpoint of reducing a cost of consumables in the manufacture of substrates and a quality of the substrate.

Since the new elastic membrane does not have sufficient elasticity (flexibility), a process (i.e., a break-in process) is performed to prepare the new elastic membrane in a state in which it can be used to manufacture the substrate. Conventionally, the break-in process involves polishing a dummy wafer (non-product wafer) using a newly replaced elastic membrane, thereby bringing the elastic membrane into a state in which it can be used to manufacture the substrate. The break-in process of the elastic membrane interrupts the process of manufacturing the substrate (downtime).

Furthermore, even if the number of dummy wafers required for the break-in process is polished, if the break-in process is insufficient, the dummy wafers must be polished again and the break-in process must be performed again until the elastic membrane is in a state where it can process the substrate, which increases downtime. As a result, an operating rate of the polishing apparatus decreases. On the other hand, excessive break-in processing increases the downtime of the apparatus and wastes consumables such as slurry. From this perspective, it is desirable to appropriately determine the state of the elastic membrane (more specifically, the time when the break-in process is completed).

Therefore, there is provided an initialization device for an elastic membrane and an initialization method for the elastic membrane that can accurately improve an elasticity of the elastic membrane.

There is provided a polishing apparatus and a life determination method for the elastic membrane that can accurately determine a replacement time of the elastic membrane.

### Solution to Problem

In an embodiment, there is provided an initialization device for an elastic membrane comprising: a pressurizing device configured to pressurize the elastic membrane attachable to a substrate holding mechanism of a polishing apparatus to expand the elastic membrane; an expansion amount detection device configured to detect an expansion amount of the elastic membrane; and a control device configured to compare the expansion amount detected by the expansion amount detection device with a predetermined target expansion amount and, when the expansion amount reaches the target expansion amount, determine a completion of an initialization of the elastic membrane.

In an embodiment, the initialization device for the elastic membrane comprises an attachment portion configured to attach an elastic membrane assembly holding the elastic membrane.

In an embodiment, the control device is configured to repeat a pressurizing operation by the pressurizing device until the expansion amount of the elastic membrane reaches the target expansion amount.

In an embodiment, the pressurizing device comprises: a ring-shaped pressing jig arranged in a pressure chamber of the elastic membrane; and a biasing device configured to press the pressing jig against the elastic membrane.

In an embodiment, the pressurizing device comprises a pressure regulating device configured to supply a pressurized fluid to a pressure chamber of the elastic membrane and open the pressure chamber of the elastic membrane to an atmosphere.

In an embodiment, the initialization device for the elastic membrane comprises a heating structure configured to heat the elastic membrane.

In an embodiment, the initialization device for the elastic membrane comprises: a rotation mechanism configured to rotate the elastic membrane; and a pad member against which the elastic membrane is pressed, and the control device is configured to: operate the pressurizing device to press the elastic membrane against the pad member; and operate the rotation mechanism to rotate the elastic membrane while pressing the elastic membrane against the pad member.

In an embodiment, there is provided a polishing apparatus comprising: a substrate holding mechanism to which an elastic membrane is attached; a pressurizing device configured to pressurize the elastic membrane to expand the elastic membrane; an expansion amount detection device configured to detect an expansion amount of the elastic membrane; and a control device configured to compare the expansion amount detected by the expansion amount detection device with a predetermined set expansion amount.

In an embodiment, the set expansion amount corresponds to a target expansion amount indicating a target elasticity of the elastic membrane, and when the expansion amount reaches the target expansion amount, the control device is configured to complete an initialization of the elastic membrane.

In an embodiment, the set expansion amount corresponds to a replacement expansion amount indicating a replacement time of the elastic membrane, and when the expansion amount reaches the replacement expansion amount, the control device is configured to issue a signal regarding the replacement time of the elastic membrane.

In an embodiment, the control device is configured to: measure a release time until the substrate held by the substrate holding mechanism is released from the elastic membrane; and determine the replacement time of the elastic membrane based on the measured release time and the calculated expansion amount.

In an embodiment, there is provided an initialization method for an elastic membrane attachable to a substrate holding mechanism of a polishing apparatus, comprising: pressurizing the elastic membrane by a pressurizing device to expand the elastic membrane; detecting an expansion amount of the elastic membrane by an expansion amount detection device; and comparing the expansion amount detected by the expansion amount detection device with a predetermined target expansion amount, when the expansion amount reaches the target expansion amount, to determine a completion of an initialization of the elastic membrane.

In an embodiment, the initialization method for the elastic membrane comprises: attaching an elastic membrane assembly holding the elastic membrane to an initialization device provided separately from the polishing apparatus; and expanding the elastic membrane by the pressurizing device without holding a substrate to initialize the elastic membrane.

In an embodiment, the initialization method for the elastic membrane comprises repeating a pressurizing operation by the pressurizing device until the expansion amount of the elastic membrane reaches the target expansion amount.

In an embodiment, the initialization method for the elastic membrane comprises heating the elastic membrane.

In an embodiment, the initialization method for the elastic membrane comprises: pressing the elastic membrane against a pad member; and rotating the elastic membrane while pressing the elastic membrane against the pad member.

In an embodiment, the initialization method for the elastic membrane comprises polishing a dummy wafer by the substrate holding mechanism to which the elastic membrane is attached to initialize the elastic membrane.

In an embodiment, there is provided a life determination for an elastic membrane comprising: pressurizing the elastic membrane by a pressurizing device to expand the elastic membrane; detecting an expansion amount of the elastic membrane by an expansion amount detection device; and comparing the expansion amount detected by the expansion amount detection device with a predetermined replacement expansion amount, when the expansion amount reaches the replacement expansion amount, to determine a replacement time of the elastic membrane.

In an embodiment, the life determination for the elastic membrane comprises: measuring a release time until a substrate held by a substrate holding mechanism, to which the elastic membrane is attached, is released from the elastic membrane; and determining the replacement time of the elastic membrane based on the measured release time and the calculated expansion amount.

### Advantageous Effects of Invention

The control device can improve the elasticity of the elastic membrane precisely, without excess or deficiency, by comparing an expansion amount of the elastic membrane with a target expansion amount.

### BRIEF DESCRIPTION OF DRAWINGS

FIG. 1 is a view showing one embodiment of a polishing unit;

FIG. 2 is a cross-sectional view showing a polishing head;

FIG. 3 is a schematic view showing a pressure regulating device;

FIG. 4 is a schematic view showing a state in which an elastic membrane assembly is removed from the polishing head shown in FIG. 2;

FIG. 5 is a view showing one embodiment of an initialization device;

FIG. 6 is a view showing a pressurizing device and an expansion amount detection device;

FIG. 7 is a view showing the pressurizing device;

FIG. 8A is a view showing an expansion amount detection device as a transmission type optical sensor;

FIG. 8B is a view showing an expansion amount detection device as a reflection type optical sensor;

FIG. 9 is a view showing another embodiment of the expansion amount detection device;

FIG. 10 is a view showing another embodiment of the expansion amount detection device;

FIG. 11 is a view showing a changing moire fringe image;

FIG. 12 is a view showing a control flow of an initialization process for the elastic membrane by a control device;

FIG. 13A is a view showing several embodiments of a heating structure for heating the elastic membrane;

FIG. 13B is a view showing several embodiments of a heating structure for heating the elastic membrane;

FIG. 13C is a view showing several embodiments of a heating structure for heating the elastic membrane;

FIG. 13D is a view showing several embodiments of a heating structure for heating the elastic membrane;

FIG. 14 is a view showing a rotation mechanism for rotating the elastic membrane;

FIG. 15 is a view showing another embodiment of the pressure regulating device;

FIG. 16 is a view showing a polishing apparatus including the polishing unit and a transfer station;

FIG. 17 is a perspective view showing a transfer station;

FIG. 18 is a view showing an expansion amount detection device arranged in the transfer station;

FIG. 19 is a view showing a control flow of a replacement time determination process of the elastic membrane by the control device; and

FIG. 20 is a view showing a control flow of the replacement time determination process of the elastic membrane by the control device.

### DESCRIPTION OF EMBODIMENTS

Hereinafter, embodiments of the present invention will be described with reference to the drawings.

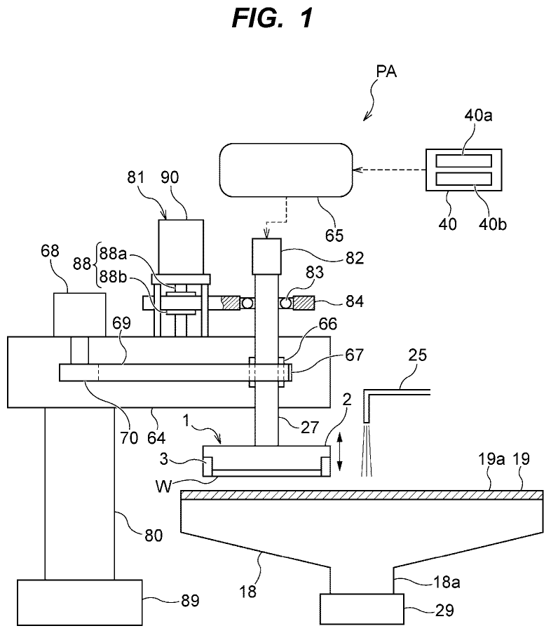

FIG. 1 is a view showing one embodiment of a polishing unit. The polishing unit PA is one of components of a polishing apparatus. As shown in FIG. 1, the polishing unit PA includes a polishing table 18 that supports a polishing pad 19, and a polishing head (substrate holding mechanism or substrate holding device) 1 that holds a wafer W, as an example of a substrate, and presses it against the polishing pad 19 on the polishing table 18.

The polishing table 18 is coupled to a table motor 29 arranged below the polishing table 18 via a table shaft 18a and is rotatable about the table shaft 18a. The polishing pad 19 is attached to an upper surface of the polishing table 18, and a surface 19a of the polishing pad 19 constitutes a polishing surface for polishing the wafer W. The polishing pad 19 is supported by the polishing table 18.

A processing liquid supply nozzle 25 is provided above the polishing table 18, and this processing liquid supply nozzle 25 supplies a processing liquid consisting of a polishing liquid, a cleaning liquid (e.g., pure water), or other liquid onto the polishing pad 19 on the polishing table 18.

The polishing head 1 includes a head main body 2 that presses the wafer W against the polishing surface 19a, and a retaining ring 3 that holds the wafer W to prevent it from jumping out of the polishing head 1. The polishing head 1 is connected to a head shaft 27, which is movable up and down relative to the head arm 64 by a vertical movement device 81. A vertical movement of the head shaft 27 raises and lowers the entire polishing head 1 relative to the head arm 64 for positioning. A rotary joint 82 is attached to an upper end of the head shaft 27.

The vertical movement device 81, which moves the head shaft 27 and the polishing head 1 up and down, includes a bridge 84 that rotatably supports the head shaft 27 via a bearing 83, a ball screw 88 attached to the bridge 84, and a servo motor 90.

The ball screw 88 includes a screw shaft 88a coupled to the servo motor 90 and a nut 88b into which the screw shaft 88a is screwed. The head shaft 27 moves up and down together with the bridge 84. Therefore, when the servo motor 90 is driven, the bridge 84 moves up and down via the ball screw 88, whereby the head shaft 27 and the polishing head 1 move up and down.

The head shaft 27 is coupled to a rotating cylinder 66 via a key (not shown). The rotating cylinder 66 includes a timing pulley 67 on an outer peripheral portion of the rotating cylinder 66. A head motor 68 is fixed to the head arm 64, and the timing pulley 67 is connected to a timing pulley 70 provided on the head motor 68 via a timing belt 69.

Therefore, by rotating the head motor 68, the rotating cylinder 66 and the head shaft 27 rotate together via the timing pulley 70, the timing belt 69, and the timing pulley 67, thereby rotating the polishing head 1. The head arm 64 is supported by an arm shaft 80 that is rotatably supported on a frame (not shown). The polishing unit PA includes a control device 40 that controls each device within devices, including the head motor 68, the servo motor 90, and the vertical movement device 81.

The control device 40 includes a storage device 40a in which programs, data, etc. are stored, and a processing device 40b such as a CPU (Central Processing Unit) that performs calculations according to the programs stored in the storage device 40a. The programs cause the processing device 40b to perform an initialization operation (described later) for the elastic membrane 10 and/or a life determination operation (described later) for the elastic membrane 10.

A program for causing the processing device 40b to perform the above-described operations is stored in a computer-readable storage medium, which is a non-transitory tangible item, and is provided to the control device 40 via the storage medium. Alternatively, the program may be input to the control device 40 from a communication device (not shown) via a communication network such as the Internet or a local area network.

The polishing head 1 is configured to be able to hold the wafer W on a lower surface of the polishing head 1. The head arm 64 is coupled to an arm motor 89 arranged below it via an arm shaft 80, and is able to rotate around the arm shaft 80. The control device 40 is electrically connected to the arm motor 89, and is configured to control the arm motor 89 as a swivel device that swivels the polishing head 1.

The head arm 64 is configured to swivel around the arm shaft 80, and the polishing head 1 holding the wafer W on the lower surface of the polishing head 1 is moved from a receiving position (waiting position) for the wafer W to above the polishing pad 19 by swiveling the head arm 64.

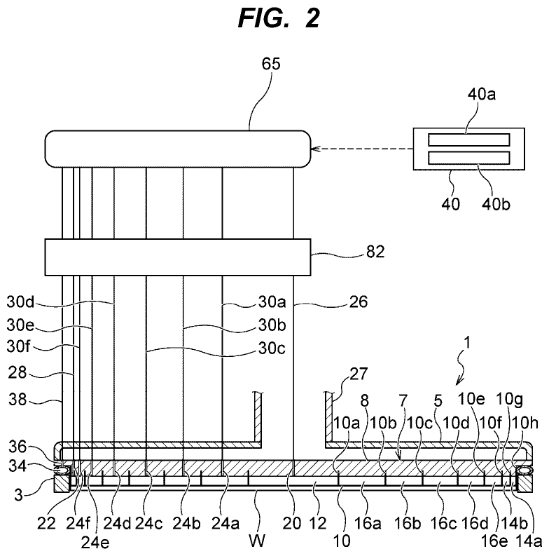

The polishing of the wafer W is performed as follows. The polishing head 1 and the polishing table 18 are each rotated, and a polishing liquid is supplied onto the polishing pad 19 from the processing liquid supply nozzle 25 provided above the polishing table 18. In this state, the polishing head 1 is lowered to a predetermined position (predetermined height), and at this predetermined position, the wafer W is pressed against the polishing surface 19a of the polishing pad 19. The wafer W is brought into sliding contact with the polishing surface 19a of the polishing pad 19, thereby polishing the surface of the wafer W. The polishing head (substrate holding mechanism or substrate holding device) 1 provided in the polishing unit PA shown in FIG. 1 will be described in detail with reference to FIG. 2.

FIG. 2 is a cross-sectional view showing the polishing head. As shown in FIG. 2, the polishing head 1 includes a head base 5 fixed to a lower end of the head shaft 27, and an elastic membrane assembly 7 attached to a lower end of the head base 5. The elastic membrane assembly 7 is attached to the head base 5 via a coupling mechanism (not shown).

The elastic membrane assembly 7 includes a retaining ring 3 that directly presses against the polishing surface 19a, an elastic membrane 10 that presses the wafer W against the polishing surface 19a, and a carrier 8 to which the elastic membrane 10 is attached. The retaining ring 3 is arranged so as to surround the wafer W and the elastic membrane 10, and is coupled to the carrier 8. The elastic membrane 10 is attached to the carrier 8 so as to cover a lower surface of the carrier 8.

The elastic membrane 10 has a plurality of (eight in the figure) annular circumferential walls 10a, 10b, 10c, 10d, 10e, 10f, 10g, and 10h arranged concentrically. The circumferential wall 10h corresponds to a side wall located at an outermost peripheral portion of the elastic membrane 10. These circumferential walls 10a to 10h form a circular central pressure chamber 12 located at a center between an upper surface of the elastic membrane 10 and the lower surface of the carrier 8, annular edge pressure chambers 14a and 14b located at the outermost peripheral portion, and five annular intermediate pressure chambers (first to fifth intermediate pressure chambers) 16a, 16b, 16c, 16d, and 16e located between the central pressure chamber 12 and the edge pressure chambers 14a and 14b. In this embodiment, the number of pressure chambers formed in the elastic membrane 10 is eight, but the number of pressure chambers is not limited to this embodiment. The number of pressure chambers may be increased or decreased depending on a structure of the elastic membrane 10.

Within the carrier 8, there are formed a flow path 20 communicating with the central pressure chamber 12, a flow path 22 communicating with the edge pressure chamber 14a, a flow path 24f communicating with the edge pressure chamber 14b, and flow paths 24a, 24b, 24c, 24d, and 24e communicating with the intermediate pressure chambers 16a, 16b, 16c, 16d, and 16e, respectively.

The flow paths 20, 22, 24a, 24b, 24c, 24d, 24e, and 24f are connected to fluid lines 26, 28, 30a, 30b, 30c, 30d, 30e, and 30f, respectively, and these fluid lines are connected to a pressure regulating device 65 via a rotary joint 82. The pressure regulating device 65 is electrically connected to the control device 40, and the control device 40 can control an operation of the pressure regulating device 65. The pressure regulating device 65 constitutes a part of the polishing unit PA.

A retaining chamber 34 is formed directly above the retaining ring 3, and the retaining chamber 34 is connected to the pressure regulating device 65 via a flow path 36 and a fluid line 38 formed in the carrier 8.

While holding the wafer W by the polishing head 1, the control device 40 controls a pressure of a pressurized fluid supplied to each of the pressure chambers 12, 14a, 14b, 16a to 16e, thereby pressing the wafer W with different pressures in each of areas on the elastic membrane 10 along a radial direction of the wafer W.

In this manner, the control device 40 can adjust the pressure of the fluid supplied to each of the pressure chambers 12, 14a, 14b, 16a to 16e formed between the carrier 8 and the elastic membrane 10, thereby adjusting a pressing force applied to the wafer W for each region of the wafer W. Similarly, the control device 40 can adjust a pressing force with which the retaining ring 3 presses the polishing pad 19 by controlling the pressure of the pressurized fluid supplied to the retaining chamber 34.

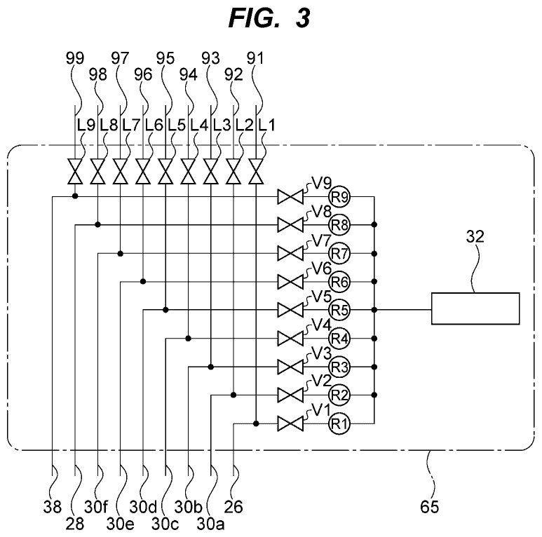

The carrier 8 is formed of a resin such as an engineering plastic (e.g., PEEK), and the elastic membrane 10 is formed of a rubber material having excellent strength and durability such as ethylene propylene rubber (EPDM), polyurethane rubber, silicone rubber, etc. The pressure regulating device 65 will be described in detail with reference to FIG. 3.

FIG. 3 is a schematic view showing the pressure regulating device. As shown in FIG. 3, the fluid lines 26, 28, 30a to 30f, and 38 are provided with on-off valves V1, V2, V3, V4, V5, V6, V7, V8, and V9 and pressure regulators R1, R2, R3, R4, R5, R6, R7, R8, and R9, respectively. As shown in FIG. 3, the fluid lines 26, 28, 30a, 30b, 30c, 30d, 30e, 30f, and 38 are connected to a fluid supply source 32.

Atmospheric release lines 91 to 99 are connected to the fluid lines 26, 30a to 30f, 28, and 38. Atmospheric release valves L1 to L9 are attached to these atmospheric release lines 91 to 99, respectively.

The pressure regulators R1 to R9 each have a pressure regulating function of regulating pressures of the pressurized fluid supplied from the fluid supply source 32 to the pressure chambers 12, 14a, 14b, 16a to 16e and the retaining chamber 34. The pressure regulators R1 to R9, the on-off valves V1 to V9, and the atmosphere relief valves L1 to L9 are connected to the control device 40, which is configured to control their operations. When the atmosphere relief valves L1 to L9 are operated, the chambers 12, 14a, 14b, 16a to 16e, and 34 are opened to the atmosphere and are at atmospheric pressure.

Although not shown, vacuum lines are connected to the fluid lines 26, 28, 30a, 30b, 30c, 30d, 30e, 30f, and 38, respectively, and negative pressure is created through these vacuum lines in the chambers 12, 14a, 14b, 16a to 16e, and 34. In this manner, the pressure in each of the chambers 12, 14a, 14b, 16a to 16e, and 34 is regulated by the pressure regulating device 65 to any one of a pressurized state, a negative pressure state, and an atmospheric pressure state.

When a vacuum is formed in the intermediate pressure chamber 16c with the wafer W in contact with a lower surface of the elastic membrane 10, the wafer W is held by vacuum suction to the polishing head 1. Furthermore, when a pressurized fluid is supplied to the intermediate pressure chamber 16c with the wafer W separated from the polishing pad 19, the wafer W is released from the polishing head 1.

When the elastic membrane 10 is replaced due to the need for maintenance or the like, a new replaced elastic membrane 10 does not have sufficient elasticity (flexibility), and therefore the wafer W cannot be pressed against the polishing surface 19a of the polishing pad 19 with a desired pressing force even if a fluid having a predetermined pressure is supplied to each of the pressure chambers 12, 14a, 14b, 16a to 16e.

In this embodiment, a break-in process (in other words, an initialization process of the elastic membrane 10) is performed to improve the elasticity (flexibility) of the elastic membrane 10. Therefore, the wafer W can be pressed against the polishing surface 19a of the polishing pad 19 with a desired pressing force. As a result, the surface of the wafer W can be stably polished.

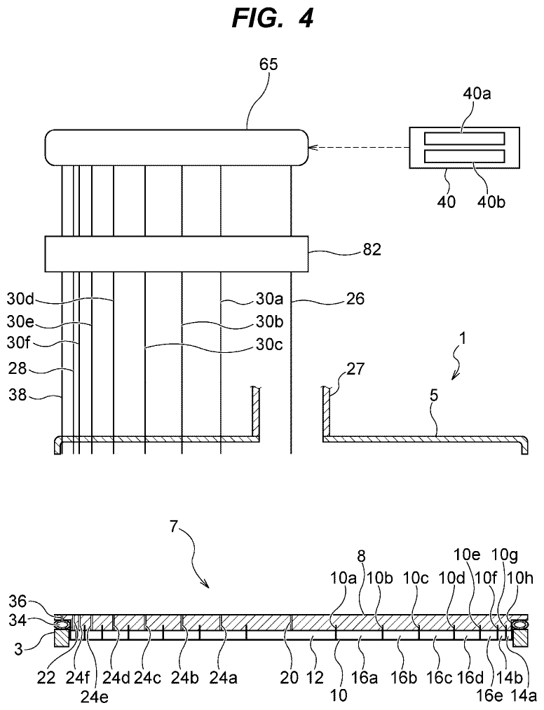

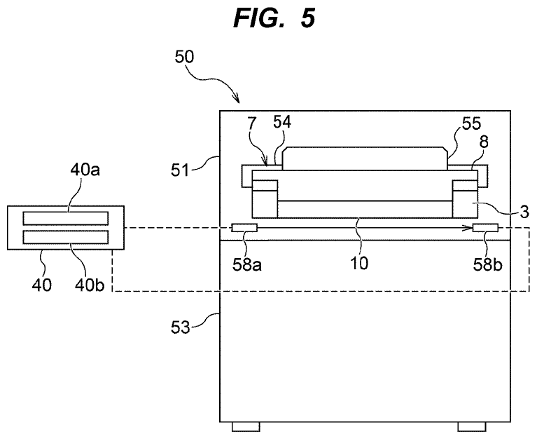

FIG. 4 is a schematic view showing a state in which the elastic membrane assembly is removed from the polishing head shown in FIG. 2. As shown in FIG. 4, the elastic membrane assembly 7 is removed from the polishing head 1. Then, the elastic membrane 10 is removed from the carrier 8 of the removed elastic membrane assembly 7, and a new elastic membrane 10 is attached to the carrier 8 of the elastic membrane assembly 7. The elastic membrane assembly 7, to which the new elastic membrane 10 is attached, is attached to an initialization device for the elastic membrane 10, which will be described later, and a break-in process for the new elastic membrane 10 is performed. Hereinafter, details of the initialization device for the elastic membrane 10 (hereinafter, sometimes simply referred to as the initialization device) will be described with reference to FIG. 5.

FIG. 5 is a view showing one embodiment of the initialization device. The initialization device 50 shown in FIG. 5 includes a pressurizing device 55 for pressurizing the elastic membrane 10 to expand the elastic membrane 10, and an expansion amount detection device 58 for detecting an expansion amount of the elastic membrane 10.

The initialization device 50 includes an accommodation box 51 that accommodates the pressurizing device 55 (and an elastic membrane assembly 7 coupled to the pressurizing device 55), a main body portion 53 on which the accommodation box 51 is placed, and an attachment portion 54 for attaching the elastic membrane assembly 7. The attachment portion 54 is configured to attach the elastic membrane assembly 7 to a predetermined position in the accommodation box 51.

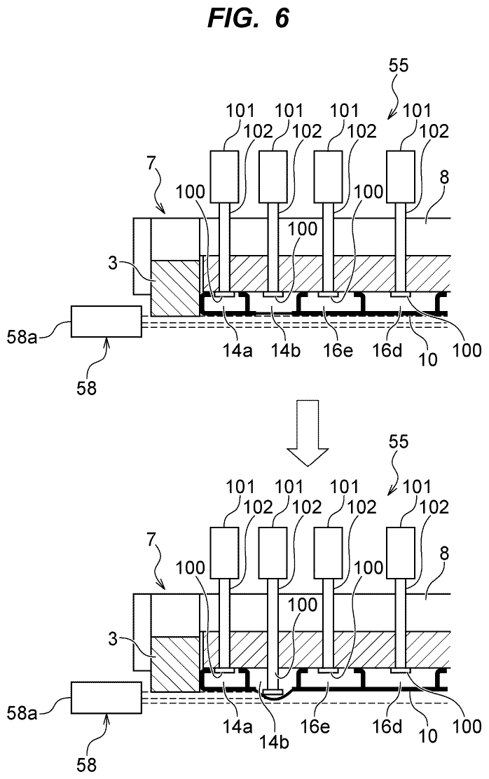

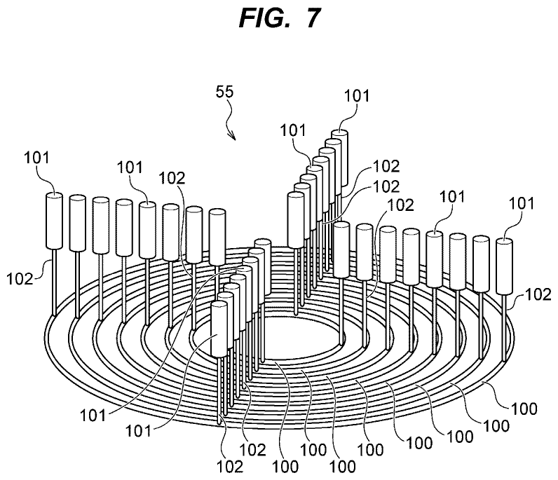

FIG. 6 is a view showing the pressurizing device and the expansion amount detection device. FIG. 7 is a view showing the pressurizing device. As shown in FIGS. 6 and 7, the pressurizing device 55 includes a ring-shaped pressing jig 100 arranged in each of the pressure chambers 12, 14a, 14b, and 16a to 16e of the elastic membrane 10, and a biasing device 101 that presses the pressing jig 100 against the elastic membrane 10 (more specifically, against the lower surface of the elastic membrane 10).

The number of pressing jigs 100 corresponds to the number of pressure chambers of the elastic membrane 10. In this embodiment, eight pressing jigs 100 are arranged concentrically along a radial direction of the elastic membrane 10. The pressurizing device 55 includes a plurality of connecting rods 102 connected to each pressing jig 100. These connecting rods 102 are arranged at equal intervals along a circumferential direction of the elastic membrane 10. The biasing device 101 is connected to each connecting rod 102, and transmits a biasing force of the biasing device 101 to the pressing jig 100 through the connecting rods 102.

In this embodiment, the number of biasing devices 101 corresponds to the number of connecting rods 102, but as long as the biasing force can be transmitted to the pressing jig 100, the number of biasing devices 101 is not limited to this embodiment.

In the embodiment shown in FIGS. 6 and 7, the biasing device 101 is an air cylinder that drives the pressing jig 100 in a direction to approach and move away from the lower surface of the elastic membrane 10. However, the biasing device 101 is not necessarily limited to an air cylinder as long as it has a structure that drives the pressing jig 100 in the direction to approach and move away from the lower surface of the elastic membrane 10. For example, the biasing device 101 may be a linear motor.

The control device 40 is electrically connected to the biasing device 101 and can control an operation of the biasing device 101. In FIG. 6, the control device 40 operates the biasing device 101 corresponding to the pressing jig 100 arranged in the pressure chamber 14b to press the pressing jig 100 against the elastic membrane 10. Thereafter, the control device 40 operates the biasing device 101 to raise the pressing jig 100.

The control device 40 may operate all of the biasing devices 101 to press the pressing jigs 100 arranged in all of the pressure chambers against the elastic membrane 10, or may operate at least one of the biasing devices 101. In this manner, the control device 40 can improve the elasticity (flexibility) of the elastic membrane 10 by operating the biasing devices 101 to lower and raise the pressing jig 100. Therefore, the initialization device 50 can uniformize the pressing force against the wafer W, and as a result, the polishing unit PA can stably polish the surface of the wafer W.

In the embodiment shown in FIG. 6, the expansion amount detection device 58 is arranged laterally on the lower surface of the elastic membrane 10 and is an optical sensor that irradiates light in the radial direction of the elastic membrane 10. The expansion amount detection device 58 is configured to detect a signal corresponding to the expansion amount of the elastic membrane 10 based on an intensity of light that changes according to the expansion amount of the elastic membrane 10. The expansion amount detection device 58 is electrically connected to the control device 40 and sends a detection signal to the control device 40. The control device 40 determines the expansion amount of the elastic membrane 10 based on the detection signal sent from the expansion amount detection device 58.

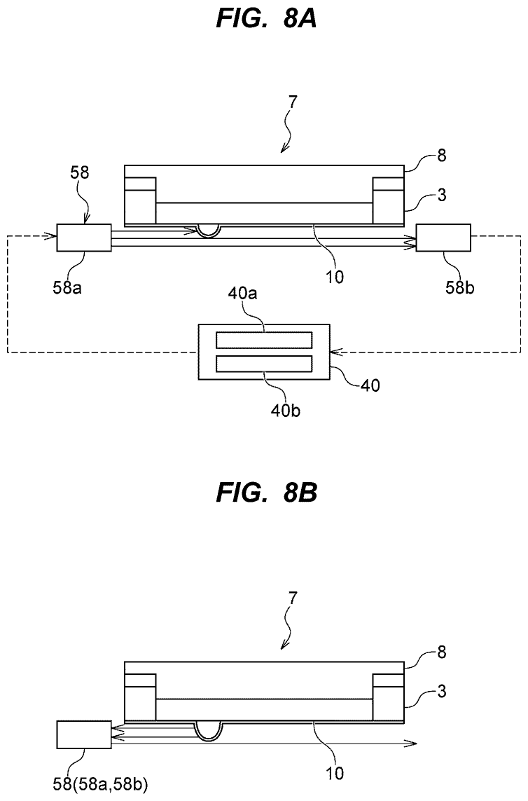

FIG. 8A is a view showing an expansion amount detection device as a transmission type optical sensor. FIG. 8B is a view showing an expansion amount detection device as a reflection type optical sensor. As shown in FIGS. 8A and 8B, a structure of the expansion amount detection device 58 as the optical sensor is not particularly limited.

As shown in FIG. 8A, the expansion amount detection device 58 may include a light emitter 58a and a light receiver 58b arranged on either side of the elastic membrane 10. In this case, the light emitted from the light emitter 58a is received by the light receiver 58b. The control device 40 determines the expansion amount of the elastic membrane 10 based on the amount (intensity) of the light received by the light receiver 58b.

More specifically, when the pressurizing device 55 pressurizes the elastic membrane 10, the elastic membrane 10 expands. The expanded elastic membrane 10 blocks at least a portion of the light emitted from the light emitter 58a. Therefore, the amount of light received by the light receiver 58b changes according to the expansion amount of the elastic membrane 10. The amount of light and the expansion amount of the elastic membrane 10 are correlated with each other, and the storage device 40a of the control device 40 stores a correlation (i.e., correlation data) between the amount of light and the expansion amount of the elastic membrane 10. The control device 40 determines the expansion amount of the elastic membrane 10 based on the signal detected by the light receiver 58b and the above correlation.

As shown in FIG. 8B, the expansion amount detection device 58 may be a reflection type optical sensor arranged on a side of the elastic membrane 10. In this case, the expansion amount detection device 58 is an optical sensor incorporating the light emitter 58a and the light receiver 58b. At least a portion of the light emitted from the expansion amount detection device 58 is reflected by the expanded elastic membrane 10, and the expansion amount detection device 58 receives the reflected light.

The amount of reflected light changes depending on the expansion amount of the elastic membrane 10, and there is a correlation between the amount of reflected light (intensity) and the expansion amount of the elastic membrane 10. The storage device 40a stores the correlation (i.e., correlation data) between the amount of reflected light and the expansion amount of the elastic membrane 10. Therefore, the control device 40 determines the expansion amount of the elastic membrane 10 based on the signal detected by the expansion amount detection device 58 and the above correlation.

When the expansion amount detection device 58 is a transmission type optical sensor or a reflection type optical sensor, the initialization device 50 may include at least one expansion amount detection device 58. When the pressurizing device 55 pressurizes the elastic membrane 10, the edge pressure chambers 14a, 14b and the intermediate pressure chambers 16a to 16e, excluding the central pressure chamber 12, expand in an annular shape as a whole. By providing the expansion amount detection devices 58, the control device 40 can accurately and three-dimensionally evaluate the expansion amount of the elastic membrane 10 based on the signals detected by the expansion amount detection devices 58.

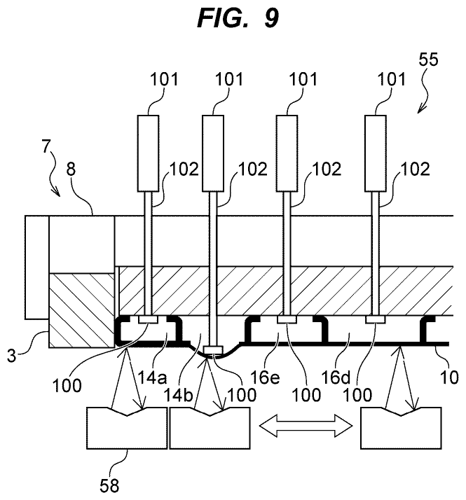

FIG. 9 is a view showing another embodiment of the expansion amount detection device. As shown in FIG. 9, the expansion amount detection device 58 may be a distance sensor that irradiates light from below the elastic membrane 10 and receives reflected light. In the embodiment shown in FIG. 9, the expansion amount detection device 58 is configured to be movable in the radial direction of the elastic membrane 10 (in this embodiment, a horizontal direction). The expansion amount detection device 58 as the distance sensor is configured to detect a signal corresponding to the expansion amount of the elastic membrane 10 based on a change in a distance between the expansion amount detection device 58 and the elastic membrane 10 due to a movement of the expansion amount detection device 58.

As shown in FIG. 9, when the pressurizing device 55 pressurizes the elastic membrane 10, the elastic membrane 10 expands. When the elastic membrane 10 expands, a distance between the lower surface of the elastic membrane 10 and the expansion amount detection device 58 changes. The storage device 40a stores a correlation (i.e., correlation data) between this distance and the expansion amount of the elastic membrane 10. Therefore, the control device 40 determines the expansion amount of the elastic membrane 10 based on the signal detected by the expansion amount detection device 58 and the above correlation.

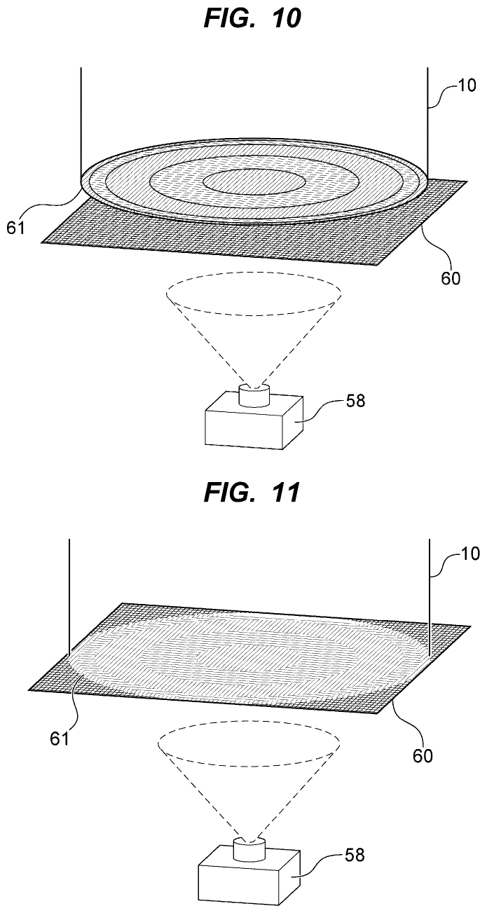

FIG. 10 is a view showing another embodiment of the expansion amount detection device. As shown in FIG. 10, the expansion amount detection device 58 may be an imaging device arranged below the elastic membrane 10. In this case, the expansion amount detection device 58 as the imaging device captures images of the elastic membrane 10 before and after expansion, and sends the captured images (detection signal) of the elastic membrane 10 to the control device 40. The control device 40 compares the captured images of the elastic membrane 10 before and after expansion, and determines the expansion amount of the elastic membrane 10 based on the changing images of the elastic membrane 10.

As shown in FIG. 10, the expansion amount detection device 58 as the imaging device may generate a moire fringe image based on a first pattern sheet 60 arranged between the expansion amount detection device 58 and the elastic membrane 10, and a second pattern sheet 61 attached to the surface of the elastic membrane 10.

FIG. 11 is a view showing a changing moire fringe image. When the pressurizing device 55 pressurizes the elastic membrane 10, the elastic membrane 10 expands, and a stripe pattern of the second pattern sheet 61 attached to the elastic membrane 10 changes. The moire fringe image changes with the change in the second pattern sheet 61, and the changed moire fringe image is captured by the expansion amount detection device 58.

The pattern of change in the moire fringe image is determined according to the expansion amount of the elastic membrane 10, and a correlation exists between the pattern of change in the moire fringe image and the expansion amount of the elastic membrane 10. The storage device 40a stores the correlation (i.e., correlation data). Therefore, the control device 40 determines the expansion amount of the elastic membrane 10 based on the signal (more specifically, the image) detected by the expansion amount detection device 58 and the above correlation.

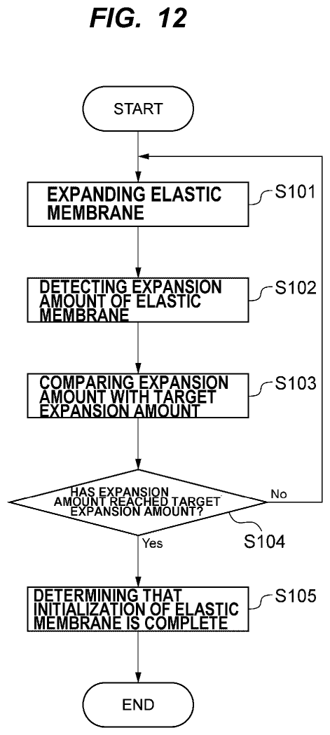

FIG. 12 is a view showing a control flow of the initialization process for the elastic membrane by the control device. As shown in step S101 of FIG. 12, the control device 40 operates the pressurizing device 55 to expand the elastic membrane 10. The expansion amount detection device 58 detects the expansion amount of the elastic membrane 10 by the expansion of the elastic membrane 10 (see step S102) and sends a detection signal to the control device 40.

The control device 40 compares the expansion amount of the elastic membrane 10 detected by the expansion amount detection device 58 with a predetermined set expansion amount (more specifically, a target expansion amount) (see step S103). The target expansion amount is a numerical value (expansion amount of the elastic membrane 10) that serves as an index showing a target elasticity of the elastic membrane 10. For example, the target expansion amount may be determined based on the expansion amount of the elastic membrane 10 that has been used in the past and that can be determined to be sufficiently initialized to provide a desired polishing performance. The target expansion amount is pre-stored in the storage device 40a.

After step S103, the control device 40 determines whether the expansion amount of the elastic membrane 10 has reached the target expansion amount (see step S104), and if the expansion amount has not reached the target expansion amount (see “NO” in step S104), the control device 40 executes steps S101 to S103 again. In this manner, the control device 40 repeats a pressurizing operation of the elastic membrane 10 by the pressurizing device 55 until the expansion amount of the elastic membrane 10 reaches the target expansion amount.

When the expansion amount reaches the target expansion amount (see “YES” in step S104), the control device 40 determines a completion of the initialization of the elastic membrane 10 (see step S105). In other words, the control device 40 completes the break-in process. The control device 40 may be configured to issue a signal regarding the completion of the initialization of the elastic membrane 10.

According to this embodiment, the control device 40 can accurately improve the elasticity of the elastic membrane 10 without excess or deficiency by comparing the expansion amount of the elastic membrane 10 detected by the expansion amount detection device 58 with the target expansion amount. In this embodiment, the break-in process of the elastic membrane 10 is performed by the initialization device 50 that is different from the polishing unit PA. Therefore, the initialization device 50 can prevent a decrease in an operating rate of the polishing apparatus due to an increase in downtime.

After the break-in process of the elastic membrane 10 is completed, the elastic membrane assembly 7 is removed from the initialization device 50 and attached to the head base 5 of the polishing head 1. Thereafter, the polishing unit PA performs trial polishing using the new elastic membrane 10 only once, and if there is no problem, polishes the wafer W as usual.

As described above, conventionally, the elasticity of the elastic membrane 10 is improved by polishing the dummy wafer with a new elastic membrane 10. Therefore, it is preferable that the initialization device 50 performs the break-in process in an environment similar to that in the case where the dummy wafer is polished with a new elastic membrane 10, as much as possible.

When a new elastic membrane 10 is used to polish a dummy wafer, frictional heat generated by polishing the dummy wafer is transmitted to the elastic membrane 10, heating the elastic membrane 10. Furthermore, the polishing head 1 rotates while holding the dummy wafer to polish the dummy wafer, and a rotational force of the polishing head 1 is transmitted to the elastic membrane 10. Therefore, the initialization device 50 may include a heating structure for heating the elastic membrane 10 and/or a rotation mechanism for rotating the elastic membrane 10.

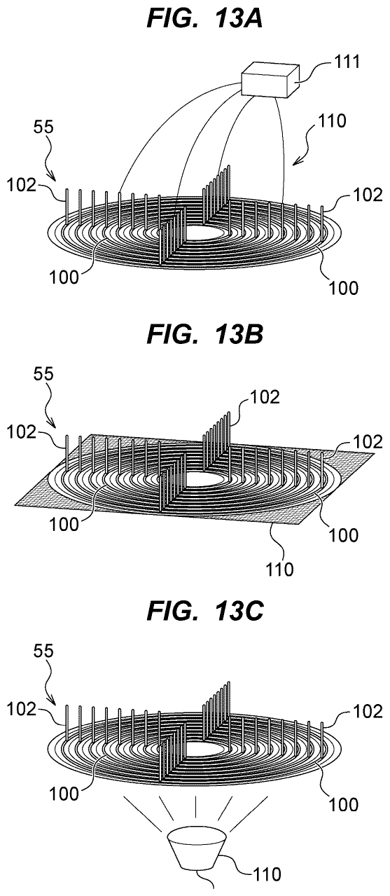

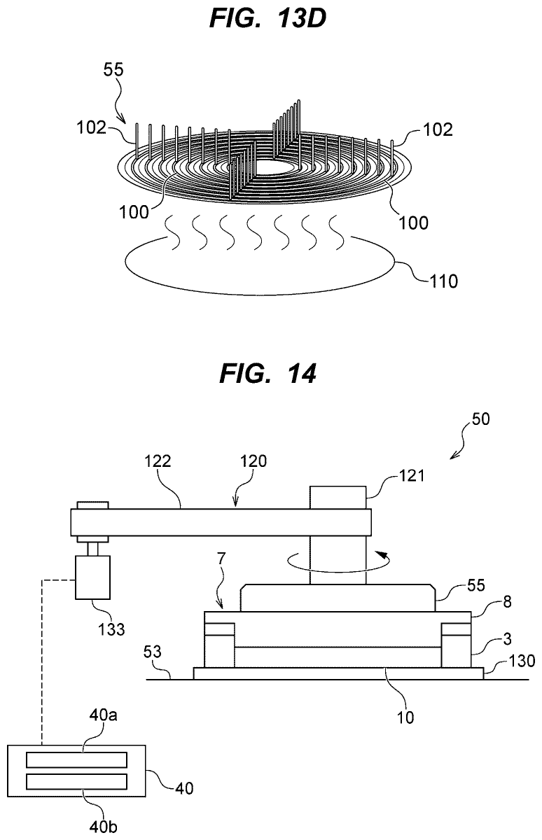

FIG. 13A to FIG. 13D are views showing several embodiments of a heating structure for heating the elastic membrane. In FIG. 13A to FIG. 13D, an illustration of the biasing device 101 is omitted for ease of viewing. The initialization device 50 includes a heating structure 110 for heating the elastic membrane 10.

In the embodiment shown in FIG. 13A, the heating structure 110 includes a combination of a heater 111 and the pressurizing device 55 (more specifically, the pressing jig 100 and the connecting rod 102) coupled to the heater 111. The heater 111 transmits heat generated by the heating to the pressing jig 100 through the connecting rod 102, thereby heating the pressing jig 100. When the biasing device 101 presses the heated pressing jig 100 against the elastic membrane 10, the elastic membrane 10 is heated. In this case, the pressing jig 100 and the connecting rod 102 may be made of a heat transfer member.

For example, when the pressing jig 100 and the connecting rod 102 have a structure in which a fluid flows therein, the heater 111 may have a structure that supplies a heated fluid to the pressing jig 100 and the connecting rod 102. For example, the heater 111 may be a nichrome wire heater that heats the pressing jig 100 and the connecting rod 102.

In the embodiment shown in FIG. 13B, the heating structure 110 includes a planar heating element arranged below the elastic membrane 10. The planar heating element has a sheet shape (or a plate shape) and is larger in size than the elastic membrane 10. When the biasing device 101 presses the pressing jig 100 against the elastic membrane 10, the elastic membrane 10 expands and comes into contact with the heating structure 110 as the planar heating element. The elastic membrane 10 is heated by this contact.

In the embodiment shown in FIG. 13C, the heating structure 110 includes a heat lamp (e.g., a halogen lamp) arranged below the elastic membrane 10. In this embodiment, the elastic membrane 10 is heated by heat emitted from the heating structure 110 as the heat lamp.

In the embodiment shown in FIG. 13D, the heating structure 110 includes a heat dissipation device (e.g., a hot air device, a far-infrared device) arranged below the elastic membrane 10. In this embodiment, the elastic membrane 10 is heated by heat emitted from the heating structure 110 as the heat dissipation device.

In FIG. 13A to FIG. 13D, the control device 40 may operate the heating structure 110 to heat the elastic membrane 10 to a temperature equivalent to the temperature of frictional heat applied to the elastic membrane 10 when polishing the wafer W held by the polishing head 1 to which the elastic membrane 10 is attached. With this configuration, the initialization device 50 can perform the break-in process in an environment similar to that in the case where a new elastic membrane 10 is used to polish a dummy wafer.

FIG. 14 is a view showing a rotation mechanism for rotating the elastic membrane. As shown in FIG. 14, the initialization device 50 includes a rotation mechanism 120 for rotating the elastic membrane 10 (more specifically, the elastic membrane assembly 7) and a pad member 130 against which the elastic membrane 10 is pressed.

The rotation mechanism 120 includes a rotation shaft 121 coupled to the elastic membrane assembly 7, and a rotation motor 123 coupled to the rotation shaft 121 via a timing belt 122. The rotation motor 123 is electrically connected to the control device 40. When the control device 40 operates the rotation motor 123, the elastic membrane assembly 7 (more specifically, the elastic membrane 10) rotates at a predetermined rotation speed via the rotation shaft 121 and the timing belt 122.

The pad member 130 is arranged between the lower surface of the elastic membrane 10 and the main body portion 53, and the lower surface of the elastic membrane 10 can contact an upper surface of the pad member 130. Therefore, the control device 40 expands the elastic membrane 10 by the pressurizing device 55 to press the elastic membrane 10 against the pad member 130. In this state, when the control device 40 operates the rotation mechanism 120 (more specifically, the rotation motor 123) to rotate the elastic membrane 10, a rotation force of the rotation shaft 121 is transmitted to the elastic membrane 10. With this configuration, the initialization device 50 can perform the break-in process under the same environment as when a new elastic membrane 10 is used to polish a dummy wafer. The control device 40 may rotate the rotation shaft 121 at the same rotation speed as the rotation speed of the polishing head 1 during polishing of the dummy wafer.

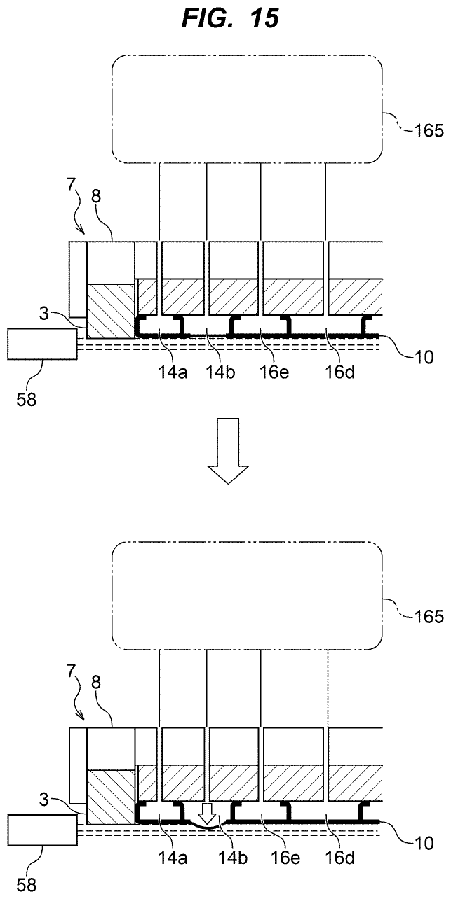

FIG. 15 is a view showing another embodiment of the pressure regulating device. In the embodiment shown in FIG. 15, the initialization device 50 also includes a pressurizing device 55. In the above-described embodiment, the configuration of the pressurizing device 55 including the pressing jig 100 and the biasing device 101 has been described, but the configuration of the pressurizing device 55 is not limited to the above-described embodiment. In one embodiment, the pressurizing device 55 includes a pressure regulating device 165 that supplies the pressurized fluid to the pressure chambers 12, 14a, 14b, 16a to 16e of the elastic membrane 10 and opens the pressure chambers 12, 14a, 14b, 16a to 16e to the atmosphere. The configuration of the pressure regulating device 165 is the same as the configuration of the pressure regulating device 65 described above (see FIG. 3), so a detailed description of the pressure regulating device 165 will be omitted.

In the embodiment shown in FIG. 15, the configuration of the pressure regulating device 165 is the same as the configuration of the pressure regulating device 65. Therefore, the control device 40 can expand the elastic membrane 10 by supplying the pressurized fluid, and improve the elasticity of the elastic membrane 10 by repeating the supply of the pressurized fluid and opening to the atmosphere as necessary.

In the embodiment, the initialization device 50 including the pressure regulating device 165 may also include the above-described expansion amount detection device 58. In one embodiment, the initialization device 50 including the pressure regulating device 165 may include a heating structure corresponding to the above-described heating structure 110 (see FIGS. 13A to 13D). Alternatively, the initialization device 50 may use a heated fluid as the pressurized fluid, thereby allowing the pressurized fluid to function as the heating structure 110.

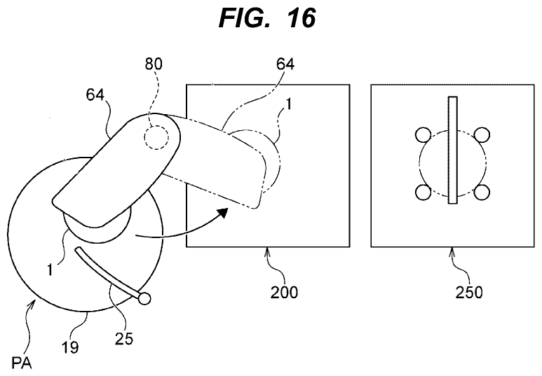

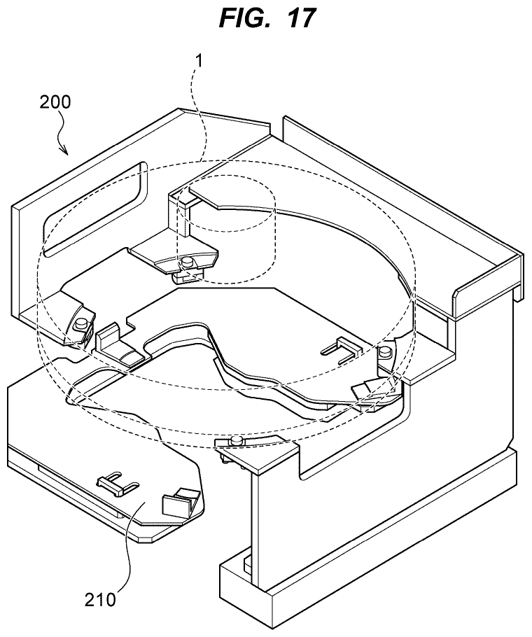

FIG. 16 is a view showing the polishing apparatus including the polishing unit and a transfer station. FIG. 17 is a perspective view showing the transfer station. The wafer W polished by the polishing unit PA is transferred to a cleaning unit 250 for cleaning the wafer W via the transfer station 200. The wafer W transferred to the cleaning unit 250 is cleaned in a cleaning module (not shown) and then dried in a drying module (not shown). In this manner, a series of processes including polishing, cleaning, and drying are performed on the wafer W.

The transfer station 200 is arranged adjacent to the polishing table 18. The transfer station 200 is provided for mounting the wafer W to the polishing head 1 and/or removing the wafer W from the polishing head 1. In this embodiment, the transfer station 200 is configured to remove the wafer W from the polishing head 1.

As shown in FIG. 16, when the head arm 64 swivels about the arm shaft 80 while the polishing head 1 holds the wafer W, the wafer W is positioned at the transfer station 200 together with the polishing head 1. A transfer stage 210 is arranged below the wafer W transferred to the transfer station 200. The wafer W released from the polishing head 1 is received by the transfer stage 210 and transferred to the cleaning unit 250.

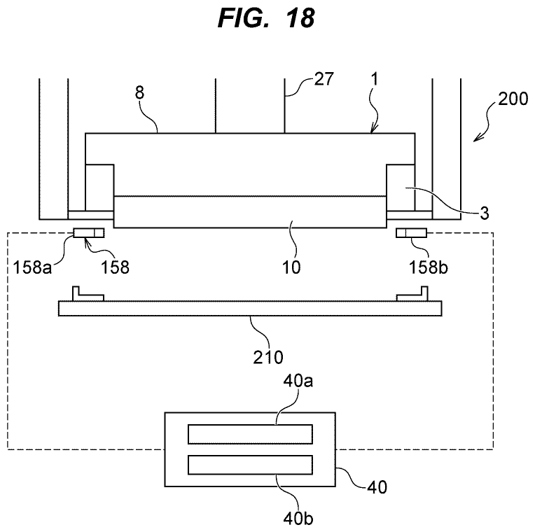

FIG. 18 is a view showing an expansion amount detection device arranged in the transfer station. As shown in FIG. 18, the polishing apparatus may include an expansion amount detection device 158 arranged in the transfer station 200. The configuration of the expansion amount detection device 158 is the same as the configuration of the expansion amount detection device 58 described above. In the embodiment shown in FIG. 18, the expansion amount detection device 158 is a transmission type optical sensor including a light emitter 158a and a light receiver 158b, but it may also be a reflection type optical sensor.

When the expansion amount detection device 158 is a transmission type optical sensor or a reflection type optical sensor, the initialization device 50 may include at least one expansion amount detection device 158. By providing the expansion amount detection devices 158, the control device 40 can accurately and three-dimensionally evaluate the expansion amount of the elastic membrane 10.

The expansion amount detection device 158 is electrically connected to the control device 40. Therefore, the control device 40 may compare the expansion amount detected by the expansion amount detection device 158 with a set expansion amount (more specifically, a target expansion amount), and determine the completion of initialization of the elastic membrane 10 when the expansion amount of the elastic membrane 10 reaches the target expansion amount.

In this embodiment, the polishing unit PA includes a pressure regulating device 65 having a configuration similar to that of the pressure regulating device 55 (more specifically, the pressure regulating device 165), and the transfer station 200 is provided with the expansion amount detection device 158 having a configuration similar to that of the expansion amount detection device 58.

More specifically, the control device 40 moves the polishing head 1 with the new elastic membrane 10 attached to the transfer station 200. In this state, the control device 40 operates the pressure regulating device 65 to supply the pressurized fluid such as compressed air from the fluid supply source 32 to at least one of the pressure chambers 12, 14a, 14b, 16a to 16e. The expansion amount detection device 158 arranged in the transfer station 200 detects the expansion amount of the elastic membrane 10. The control device 40 compares the expansion amount of the elastic membrane 10 detected by the expansion amount detection device 158 with a predetermined target expansion amount, and determines whether or not the initialization of the elastic membrane 10 has been completed (see FIG. 12).

The control device 40 may operate the pressure regulating device 65 to repeatedly supply the pressurized fluid to at least one of the pressure chambers 12, 14a, 14b, and 16a to 16e and release the pressure chamber to which the pressurized fluid has been supplied to the atmosphere. The repeated supply of the pressurized fluid and release to the atmosphere corresponds to the repeated pressurizing operation of the pressurizing device 55.

In the embodiment, the transfer station 200 may have a configuration corresponding to the heating structure 110 (see FIGS. 13A to 13D).

In this embodiment, the pad member 130 (see FIG. 14) may be provided at a position where the head arm 64 can swivel (or the delivery station 200 may have a configuration corresponding to the pad member 130). That is, the polishing head 1 rotates while pressing the elastic membrane 10 against the pad member 130, and frictional heat generated between the polishing head 1 and the pad member 130 is transmitted to the elastic membrane 10. In this case, the polishing head 1 corresponds to the rotation mechanism 120.

In one embodiment, the polishing unit PA may polish a dummy wafer with the polishing head 1 to which a new elastic membrane 10 is attached.

In this embodiment, the processing of the wafer W must be interrupted during the polishing of the dummy wafer, resulting in downtime. However, the control device 40 is configured to compare the expansion amount of the elastic membrane 10 with a predetermined target expansion amount and determine whether or not the initialization of the elastic membrane 10 has been completed, so that a problem of insufficient break-in processing does not occur. The measurement of the expansion amount of the elastic membrane 10 by the expansion amount detection device 158 can be performed during the polishing of a plurality of dummy wafers.

As described above, even if the number of dummy wafers required for the break-in process is polished, if the break-in process is insufficient, the dummy wafers must be polished again, which increases downtime.

According to this embodiment, it is possible to prevent an increase in downtime caused by insufficient break-in processing. In addition, since the completion of the break-in processing can be determined according to individual differences of the elastic membrane, it is also possible to avoid polishing an excessive number of dummy wafers. In addition, it is possible to reduce process losses such as the conventional method in which a predetermined number of dummy wafers are polished, and then a monitor wafer is polished to check the uniformity of the polishing, thereby discovering insufficient break-in processing and having to polish additional dummy wafers.

When the elastic membrane 10 is used repeatedly, the state of the elastic membrane 10 eventually changes. The elastic membrane 10 whose state has changed may adversely affect the uniformity of the pressing force applied to the wafer W, which may result in the wafer W being defective. Therefore, in the embodiment described below, a configuration that can accurately determine the replacement time of the elastic membrane 10 will be described.

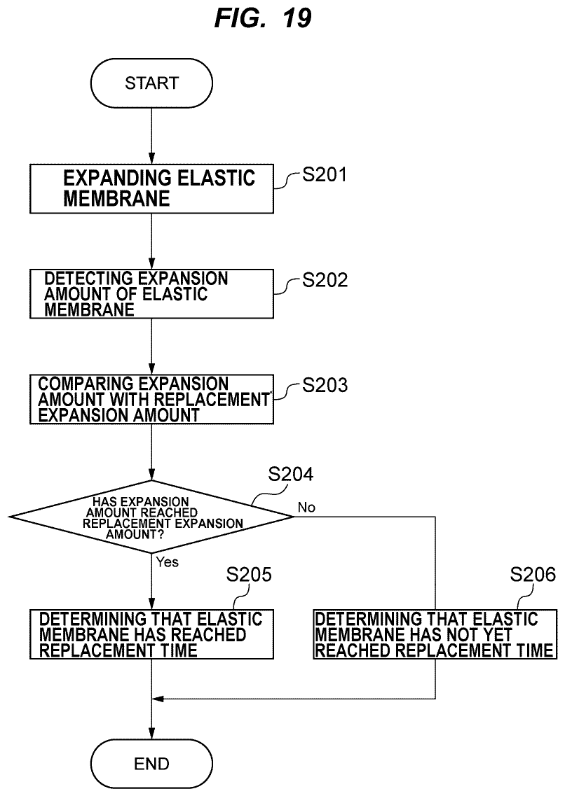

FIG. 19 is a view showing a control flow of a replacement time determination process of the elastic membrane by the control device. The replacement time of the elastic membrane 10 is determined in the transfer station 200 with the elastic membrane 10 attached to the polishing head 1. First, the control device 40 moves the polishing head 1 to which the elastic membrane 10 is attached, to the transfer station 200.

In this state, the control device 40 operates the pressure regulating device 65 to supply the pressurized fluid to at least one of the pressure chambers 12, 14a, 14b, 16a to 16e, thereby expanding the elastic membrane 10 (see step S201). The expansion amount detection device 158 arranged in the transfer station 200 detects the expansion amount of the elastic membrane 10 (see step S202). The control device 40 compares the expansion amount of the elastic membrane 10 detected by the expansion amount detection device 158 with a predetermined set expansion amount (more specifically, a replacement expansion amount) (see step S203). The replacement expansion amount is a numerical value (a stretch amount of the elastic membrane 10) that is an index of the elasticity of the elastic membrane 10, indicating the replacement time of the elastic membrane. Generally, when the state of the elastic membrane 10 changes, the expansion amount of the elastic membrane 10 becomes smaller (or larger) than that of the normal elastic membrane 10.

After step S203, the control device 40 judges whether or not the expansion amount of the elastic membrane 10 reaches the replacement expansion amount (see step S204), and if the expansion amount reaches the replacement expansion amount (see “YES” in step S204), the control device 40 determines that the elastic membrane 10 has reached the replacement time (see step S205). If the expansion amount has not reached the replacement expansion amount (see “NO” in step S204), the control device 40 determines that the elastic membrane 10 has not yet reached the replacement time (see step S206).

When the wafer W is released from the transfer station 200, a fluid (e.g., pure water, inert gas, etc.) is sprayed into the gap between the wafer W and the lower surface of the elastic membrane 10. If the elastic membrane 10 has reached the replacement time, the elastic membrane 10 has an elastic force different from that of a normal elastic membrane 10. For example, the elastic membrane 10 may be hardened due to a change in its state. In this case, the elastic membrane 10 that holds the wafer W hardly stretches, and therefore the fluid cannot be appropriately supplied between the wafer W and the lower surface of the elastic membrane 10, and as a result, the time required to release the wafer W may be extended.

Conversely, the elastic membrane 10 may be softened due to a change in its state. In this case, the elastic membrane 10 holding the wafer W may be stretched more than necessary, which may result in a longer time required to remove the wafer W.

Therefore, the control device 40 may measure a release time until the wafer W held by the polishing head 1 to which the elastic membrane 10 is attached is released from the elastic membrane 10, and determine the replacement time of the elastic membrane 10 based on the measured released time.

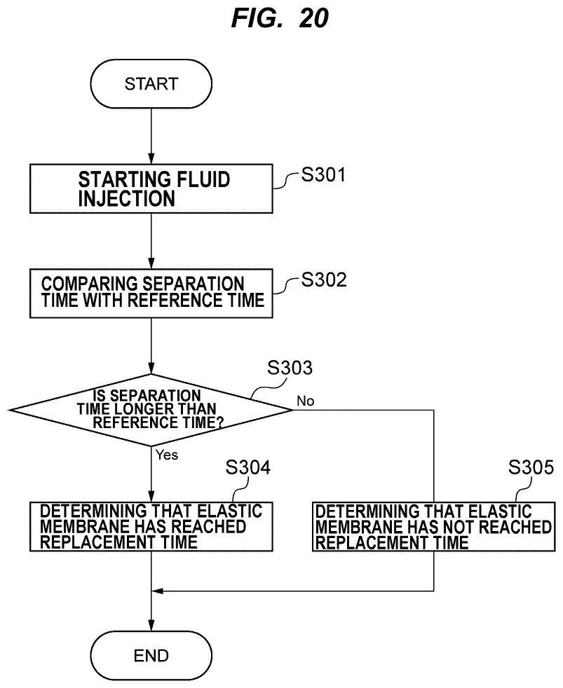

FIG. 20 is a view showing a control flow of the replacement time determination process of the elastic membrane by the control device. As shown in step S301 of FIG. 20, the control device 40 operates a release nozzle (not shown) to start spraying a fluid into the gap between the wafer W and the elastic membrane 10. Thereafter, the control device 40 measures the release time of the wafer W. The release time of the wafer W is, for example, the time from when spraying of the fluid starts to when the wafer W is received by the transfer stage 210.

The control device 40 compares the release time with a predetermined reference time (see step S302) and determines whether or not the release time is longer than the reference time (see step S303). The above described reference time is a time that serves as an indicator of the replacement time of the elastic membrane 10. If the release time is longer than the reference time (see “YES” in step S303), the control device 40 determines that the elastic membrane 10 has reached the replacement time (see step S304). If the release time is not longer than the reference time (see “NO” in step S303), the control device 40 determines that the elastic membrane 10 has not yet reached the replacement time (see step S305).

The embodiment shown in FIG. 19 may be combined with the embodiment shown in FIG. 20. In this case, the control device 40 determines the replacement time of the elastic membrane 10 based on two factors: the expansion amount of the elastic membrane 10 and the release time of the elastic membrane 10.

The above embodiments are described for the purpose of practicing the present invention by a person with ordinary skill in the art to which the invention pertains. Although preferred embodiments have been described in detail above, it should be understood that the present invention is not limited to the illustrated embodiments, but many changes and modifications can be made therein without departing from the appended claims.

### INDUSTRIAL APPLICABILITY

The present invention is applicable to an initialization device for an elastic membrane, a polishing apparatus, an initialization method for an elastic membrane, and a life determination method for an elastic membrane.

Reference Signs List

| | |
|---|---|
| 1 | polishing head |
| 2 | head main body |
| 3 | retaining ring |
| 5 | head base |
| 7 | elastic membrane assembly |
| 8 | carrier |
| 10 | elastic membrane |
| 10a~10h | circumferential wall |
| 12 | Central pressure chamber |
| 14a, 14b | edge pressure chamber |
| 16a~16e | intermediate pressure chamber |
| 18 | polishing table |
| 18a | table shaft |
| 19 | polishing pad |
| 19a | polishing surface |
| 20, 22, 24a~24f | flow path |
| 25 | processing liquid supply nozzle |
| 26, 28, 30a~30f | fluid line |
| 27 | head shaft |
| 29 | table motor |
| 32 | fluid supply source |
| 34 | retaining chamber |
| 36 | flow path |
| 38 | fluid line |
| 40 | control device |
| 40a | storage device |
| 40b | processing device |
| 50 | initialization device |
| 51 | accommodation box |
| 53 | main body portion |
| 54 | attachment portion |
| 55 | pressurizing device |
| 58 | expansion amount detection device |
| 58a | light emitter |
| 58b | Light receiver |
| 60 | first pattern sheet |
| 61 | second pattern sheet |
| 64 | head arm |
| 65 | pressure regulating device |
| 66 | rotating cylinder |
| 67 | timing pulley |
| 68 | head motor |
| 70 | timing pulley |
| 80 | arm shaft |
| 81 | vertical movement device |
| 82 | rotary joint |
| 83 | bearing |
| 84 | bridge |
| 88 | ball screw |
| 88a | screw shaft |
| 88b | nut |
| 90 | servo motor |
| 91~99 | atmospheric release valve |
| 100 | pressing jig |
| 101 | biasing device |
| 102 | connecting rod |
| 110 | heating structure |
| 111 | heater |
| 120 | rotation mechanism |
| 121 | rotation shaft |
| 122 | timing belt |
| 123 | rotation motor |
| 130 | pad member |
| 158 | expansion amount detection device |
| 158a | light emitter |
| 158b | light receiver |
| 165 | pressure regulating device |
| 200 | transfer station |
| 210 | transfer stage |
| 250 | cleaning unit |

1. An initialization device for an elastic membrane comprising:
a pressurizing device configured to pressurize the elastic membrane attachable to a substrate holding mechanism of a polishing apparatus to expand the elastic membrane;
an expansion amount detection device configured to detect an expansion amount of the elastic membrane; and
a control device configured to compare the expansion amount detected by the expansion amount detection device with a predetermined target expansion amount and, when the expansion amount reaches the target expansion amount, determine a completion of an initialization of the elastic membrane.

2. The initialization device for the elastic membrane according to claim 1, comprising an attachment portion configured to attach an elastic membrane assembly holding the elastic membrane.

3. The initialization device for the elastic membrane according to claim 1, wherein the control device is configured to repeat a pressurizing operation by the pressurizing device until the expansion amount of the elastic membrane reaches the target expansion amount.

4. The initialization device for the elastic membrane according to claim 1,
wherein the pressurizing device comprises:
a ring-shaped pressing jig arranged in a pressure chamber of the elastic membrane; and
a biasing device configured to press the pressing jig against the elastic membrane.

5. The initialization device for the elastic membrane according to claim 1, wherein the pressurizing device comprises a pressure regulating device configured to supply a pressurized fluid to a pressure chamber of the elastic membrane and open the pressure chamber of the elastic membrane to an atmosphere.

6. The initialization device for the elastic membrane according to claim 1, wherein the initialization device for the elastic membrane comprises a heating structure configured to heat the elastic membrane.

7. The initialization device for the elastic membrane according to claim 1,
wherein the initialization device for the elastic membrane comprises:
a rotation mechanism configured to rotate the elastic membrane; and
a pad member against which the elastic membrane is pressed, and
wherein the control device is configured to:
operate the pressurizing device to press the elastic membrane against the pad member; and
operate the rotation mechanism to rotate the elastic membrane while pressing the elastic membrane against the pad member.

8. A polishing apparatus comprising:
a substrate holding mechanism to which an elastic membrane is attached;
a pressurizing device configured to pressurize the elastic membrane to expand the elastic membrane;
an expansion amount detection device configured to detect an expansion amount of the elastic membrane; and
a control device configured to compare the expansion amount detected by the expansion amount detection device with a predetermined set expansion amount.

9. The polishing apparatus according to claim 8,
wherein the set expansion amount corresponds to a target expansion amount indicating a target elasticity of the elastic membrane, and
wherein when the expansion amount reaches the target expansion amount, the control device is configured to complete an initialization of the elastic membrane.

10. The polishing apparatus according to claim 8,
wherein the set expansion amount corresponds to a replacement expansion amount indicating a replacement time of the elastic membrane, and
wherein when the expansion amount reaches the replacement expansion amount, the control device is configured to issue a signal regarding the replacement time of the elastic membrane.

11. The polishing apparatus according to claim 10,
wherein the control device is configured to:
measure a release time until the substrate held by the substrate holding mechanism is released from the elastic membrane; and
determine the replacement time of the elastic membrane based on the measured release time and the calculated expansion amount.

12. An initialization method for an elastic membrane attachable to a substrate holding mechanism of a polishing apparatus, comprising:
pressurizing the elastic membrane by a pressurizing device to expand the elastic membrane;
detecting an expansion amount of the elastic membrane by an expansion amount detection device; and
comparing the expansion amount detected by the expansion amount detection device with a predetermined target expansion amount, when the expansion amount reaches the target expansion amount, to determine a completion of an initialization of the elastic membrane.

13. The initialization method for the elastic membrane according to claim 12, comprising:
attaching an elastic membrane assembly holding the elastic membrane to an initialization device provided separately from the polishing apparatus; and
expanding the elastic membrane by the pressurizing device without holding a substrate to initialize the elastic membrane.

14. The initialization method for the elastic membrane according to claim 12, comprising repeating a pressurizing operation by the pressurizing device until the expansion amount of the elastic membrane reaches the target expansion amount.

15. The initialization method for the elastic membrane according to claim 12, comprising heating the elastic membrane.

16. The initialization method for the elastic membrane according to claim 12, comprising:
pressing the elastic membrane against a pad member; and
rotating the elastic membrane while pressing the elastic membrane against the pad member.

17. The initialization method for the elastic membrane according to claim 12, comprising polishing a dummy wafer by the substrate holding mechanism to which the elastic membrane is attached to initialize the elastic membrane.

18. (canceled)

19. (canceled)
